(19) United States
(12) Patent Application Publication
(10) Pub. No.: US 2010/0237448 A1
(43) Pub. Date: Sep. 23, 2010

(54) SEMICONDUCTOR MEMORY DEVICE INCLUDING MAGNETIC TUNNEL JUNCTION ELEMENT AND FABRICATION METHOD THEREFOR

(76) Inventor: Seung A. SHIN, Seoul (KR)

Correspondence Address: IP & T Law Firm PLC, 7700 Little River Turnpike, Suite 207, Annandale, VA, 22003, US

(21) Appl. No.: 12/707,165

(22) Filed: Feb. 17, 2010

(30) Foreign Application Priority Data
Mar. 18, 2009 (KR) 10-2009-0022945

(51) Int. Cl. H01L 29/84; H01L 21/04

(52) U.S. Cl. 257/421; 438/3; 257/E21.04; 257/E29.324

(57) ABSTRACT

A method for fabricating a semiconductor memory device. An interlayer dielectric layer is formed over a semiconductor substrate including a Metal-Oxide-Semiconductor Field-Effect Transistor (MOSFET) as a cell transistor and a plurality of contact plugs in contact with source and drain regions of the cell transistor. A plurality of openings exposing one of the contact plugs is formed by removing a portion of the interlayer dielectric layer. A fixed magnetization layer, a tunnel barrier layer, and a free magnetization layer are sequentially stacked over the interlayer dielectric layer including the openings. A magnetic tunnel junction element is formed by planarizing the interlayer dielectric layer until a surface of the interlayer dielectric layer is exposed. The magnetic tunnel junction element includes the fixed magnetization layer, the tunnel barrier layer, and the free magnetization layer that fill each of the openings.

### CROSS REFERENCE TO RELATED APPLICATION

The present application claims priority to Korean Patent Application Number 10-2009-0022945 filed on Mar. 18, 2009, the entire contents of which application is incorporated herein for all purposes by this reference.

### BACKGROUND OF THE INVENTION

1. Field of the Invention

The present invention relates to Magnetic Random Access Memory (MRAM), and more particularly, to a nonvolatile memory device using a change in magnetoresistance.

2. Description of Related Art

Currently, Dynamic Random Access Memory (DRAM) is widely used as a typical memory device. DRAM has advantages, such as a high operation speed and very high density. However, since DRAM is volatile memory, the data stored therein are lost when the power supply is disconnected. The data must also be periodically refreshed by being rewritten thereto. This is a severe disadvantage in terms of power consumption. Meanwhile, flash memory, characterized by non-volatility and high density, has the disadvantage of slow operation. In contrast, Magnetoresistive Random Access Memory (MRAM), which stores information using a change in magnetoresistance, has the characteristics of non-volatility and high speed operation, as well as, the advantage of high density.

MRAM refers to a non-volatile memory device for storing data based on a change in magnetoresistance between ferromagnetic materials according to the direction of magnetization. At present, the cell structures that are most frequently used for MRAM include a Giant Magneto-Resistance (GMR) device, which uses the GMR effect, a Tunnel Magneto-Resistance (TMR) device, which uses the TMR effect, a Magnetic Tunnel Junction (MTJ) device, which uses the TMR effect, and the like. In addition, a spin-valve device, which includes a ferromagnetic layer that is reinforced by a permanent magnet layer and a soft-magnetic layer that is used as a free layer, may also be used in order to overcome the drawbacks of the GMR device. The MRJ device is particularly useful in low-power and high-speed graphics and mobile devices, since it has the characteristics of high speed and low power consumption and can replace the capacitor of DRAM.

In general, a magnetic resistance device has low resistance if two magnetic layers have the same spin direction (i.e., the same magnetic momentum direction), and high resistance if the two magnetic layers have is opposite spin directions. Based on the feature of variation in the resistance of a cell according to the magnetization of the magnetic layers, bit data can be recorded in the magnetic resistance device. This will be explained by way of example with reference to a magnetic resistance memory having an MTJ structure (i.e., an MTJ memory cell), including an insulating layer and two ferromagnetic layers. When an electron in the first ferromagnetic layer passes through the insulating layer used as a tunneling barrier, the tunneling probability varies according to the magnetization direction of the second ferromagnetic layer. The tunneling current is greatest if the magnetization directions of the two ferromagnetic layers are parallel, and is smallest if the magnetization directions of the two ferromagnetic layers are anti-parallel. Thus, a memory device may be constructed where data “1” (or “0”) is recorded if the resistance is great and data “0” (or “1”) is recorded if the resistance is small. Herein, one of the two ferromagnetic layers is referred to as a fixed magnetization layer, since its magnetization direction is fixed, and the other ferromagnetic layer is referred to as a free magnetization layer, since its magnetization direction is reversed by an external magnetic field or current.

In a typical magnetic resistance memory device, one memory cell for storing information generally includes one magnetic tunnel junction element and a selection transistor. The selection transistor selects the magnetic tunnel junction element in order to enable the recording and reading of data. In order to increase the cell density of the magnetic resistance memory device, it is necessary to reduce the volume of the memory device including the memory cell. In particular, MRAM cannot be used as a substitute for existing memory devices until a unit memory cell having an MTJ structure is miniaturized. However, it is difficult to reduce the size of the unit cell in order to produce a high density MRAM due to the superparamagnetism of magnetic layers; i.e., the magnetic layers may lose their unique magnetic properties, and exhibit a behavior similar to paramagnetism. In addition, the MTJ structure is formed by stacking heterogeneous layers having different physical properties, such as magnetic and insulating layers, over one another. However, it is difficult to etch the heterogeneous layers because the high-density integration of the memory device reduces the area in which the MTJ is to be formed.

The information disclosed in this Background of the Invention section is only for enhancement of the understanding of the background of the invention, and should not be taken as an acknowledgment or any form of suggestion that this information forms the prior art that is already known to a person skilled in the art.

### BRIEF SUMMARY OF THE INVENTION

Exemplary aspects of the present invention provide a method for fabricating a semiconductor memory device, which is advantageous for the high-density integration of a magnetic memory device.

Also provided is a memory device including a magnetic tunnel junction element having a novel structure.

In an aspect of the present invention, the method for fabricating a semiconductor memory device may include steps of forming an interlayer dielectric layer over a semiconductor substrate including a Metal-Oxide-Semiconductor Field-Effect Transistor (MOSFET), as a cell transistor, and a plurality of contact plugs in contact with source and drain regions of the cell transistor; forming a plurality of openings exposing one of the contact plugs by removing a portion of the interlayer dielectric layer; sequentially stacking a fixed magnetization layer, a tunnel barrier layer, and a free magnetization layer over the interlayer dielectric layer including the openings; and forming a magnetic tunnel junction element by planarizing the interlayer dielectric layer until a surface of the interlayer dielectric layer is exposed, wherein the magnetic tunnel junction element includes the fixed magnetization layer, the tunnel barrier layer, and the free magnetization layer that fill each of the openings.

In the step of sequentially stacking of the fixed magnetization layer, the tunnel barrier layer, and the free magnetization layer, the fixed magnetization layer may be formed to cover sidewalls and bottoms of the openings, the tunnel barrier layer may be stacked over the fixed magnetization layer to form a recess in a central portion of the openings, and the free magnetization layer may be stacked over the tunnel barrier layer to fill the recess.

The fixed magnetization layer or the free magnetization layer may be made of an alloy containing one or more metals selected from the group consisting of cobalt (Co), iron (Fe), and nickel (Ni). The fixed magnetization layer may have a stacked structure, in which ferromagnetic and antiferromagnetic layers are stacked over one another, or a synthetic antiferromagnetic structure. The tunnel barrier layer may be made of a metal or non-metal compound containing oxygen, and may contain one or more compounds selected from the group consisting of AlO, TiO, MgO, HfO, CuO, NiO, and CoO.

In another aspect of the present invention, the semiconductor memory device may include a unit memory cell including an MOSFET, as a cell transistor, and a magnetic tunnel junction element. The magnetic tunnel junction element may fill an opening in an interlayer dielectric layer. The magnetic tunnel junction element may include a fixed magnetization layer covering walls of the opening, a tunnel barrier layer stacked over the fixed magnetization layer to form a recess in a central portion of the opening, and a free magnetization layer stacked over the tunnel barrier layer to fill the recess.

The fixed magnetization layer may be connected to a drain of the cell transistor, and the fixed magnetization layer or the free magnetization layer may be made of an alloy containing one or more metals selected from the group consisting of Co, Fe, and Ni. The fixed magnetization layer may have a stacked structure, in which ferromagnetic and antiferromagnetic layers are stacked over one another, or a synthetic antiferromagnetic structure. The tunnel barrier layer may be made of a metal or non-metal compound containing oxygen, and may contain one or more compounds selected from the group consisting of AlO, TiO, MgO, HfO, CuO, NiO, and CoO.

According to exemplary embodiments of the present invention as set forth above, the magnetic tunnel junction element can be formed to have a minimal area, and the contact area between the magnetization layer and the tunnel barrier layer can be efficiently increased using the cylinder-like structure regardless of the minimization of the area in which the magnetic tunnel junction element is to be formed. Accordingly, it is possible to overcome the problem of the superparamagnetism of the magnetic tunnel junction due to the high-density integration of the magnetic memory device.

In addition, since etching is not used in the forming of the magnetic tunnel junction element, it is possible to avoid difficulties in the etching of the heterogeneous layers, which would otherwise arise due to the high-density integration of the memory device.

Accordingly, it is possible to fabricate high density magnetic memory devices, while ensuring the stable and reliable operation of the devices.

The methods and apparatuses of the present invention have other features and advantages which will be apparent from or are set forth in more detail in the accompanying drawings, which are incorporated herein, and the following Detailed Description of the Invention, which together serve to explain certain principles of the present invention.

### BRIEF DESCRIPTION OF THE DRAWINGS

FIGS. 1 to 4 are cross-sectional views showing a method for fabricating an MRAM device in accordance with an exemplary embodiment of the invention; and

FIG. 5 is a perspective view showing the structure of a magnetic tunnel junction in an MRAM device in three dimensions in accordance with an exemplary embodiment of the invention.

### DETAILED DESCRIPTION OF THE INVENTION

Reference will now be made in detail to various exemplary embodiments of the present invention illustrated in the accompanying drawings. While the invention will be described in conjunction with exemplary embodiments, it will be understood that present description is not intended to limit the invention to those exemplary embodiments. On the contrary, the invention is intended to cover not only the exemplary embodiments, but also various alternatives, modifications, and equivalents that may form other embodiments within the spirit and scope of the invention as defined by the appended claims. Above all, reference should be made to the drawings, in which the same reference numerals and signs are used throughout the different drawings to designate the same or similar components. In the following description of the present invention, a detailed description of known functions and components incorporated herein will be omitted when it may make the subject matter of the present to invention unclear.

A method for fabricating a semiconductor memory device in accordance with an exemplary embodiment of the invention will be described with reference to FIGS. 1 to 4. First, referring to FIG. 1, a cell transistor having a Metal-Oxide-Semiconductor Field-Effect Transistor (MOSFET) structure is formed on a first-conductivity-type semiconductor substrate 100. In the substrate 100, for example, an active area, in which a MOSFET is to be formed, is defined by an element isolation layer 102. A gate 110 is formed by interposing a gate insulating layer 112 over the active area. The gate 110 can be formed so as to function as a word line of a memory cell. Additionally, a capping layer 113 over the gate 110 and sidewall spacers 114 can be formed. The capping layer 113 serves to prevent the gate 110 from being damaged during subsequent processing, and the sidewall spacers 114 insulate the gate 110 from adjacent contact plugs.

In addition, source and drain diffusion regions 103s and 103d are formed by implanting second-conductivity-type dopant in predetermined areas of the substrate 100 under the gate 110. Afterwards, contact plugs 120s and 120d are formed in contact with the diffusion regions 103s and 103d, respectively. The contact plugs 120s and 120d can be formed by forming a first interlayer dielectric layer D1, followed by performing a self-aligning Landing Plug Contact (LPC) process.

Next, a source line SL is formed, in contact with an electrical path, including, for example, the source diffusion region 1035 and the contact plug 120s. Afterwards, a second interlayer dielectric layer D2 is formed over the semiconductor substrate 100, on which device structures, such as the source line SL and the cell transistor, are formed.

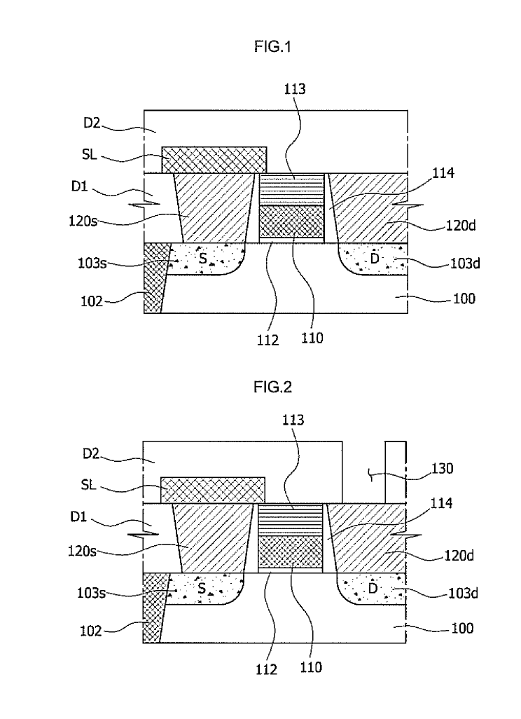

Next, referring to FIG. 2, an opening 130 is formed by removing a portion of the second interlayer dielectric layer D2 using photolithography. The opening 130 is formed so as to expose the upper surface of the contact plug 120d, which is located below the opening 130. The width and cross-sectional shape of the opening 130 can be determined according to the design of a magnetic tunnel junction element, which will be formed in the following process. For example, the opening 130 can be formed as a cylindrical hole.

Afterwards, as shown in FIG. 3, a magnetization layer 140p, an insulating layer 140b, and a magnetization layer 140f are sequentially stacked over the entire surface of the second interlayer dielectric layer D2 in which the opening 130 is formed. The magnetization layer 140p is used as a fixed magnetization layer of the magnetic tunnel junction, and is formed to a predetermined thickness to cover the sidewall and bottom of the opening 130. The insulating layer 140b is used as a tunnel barrier layer of the magnetic tunnel junction, and is formed to a predetermined thickness over the magnetization layer 140p, which is already formed over the opening 130. In particular, the insulating layer 140b is formed so as to form a recess in the center of the opening 130. In other words, it is preferred that the entrance of the opening 130 is not closed after the insulating layer 140b is formed. This is made possible by controlling process variables during the deposition of the insulating layer 140b. Subsequently, another magnetization layer 140f is stacked over the insulating layer 140b, such that it completely fills the recess defined in the insulating layer 140b. This second magnetization layer 140f is used as a free magnetization layer of the magnetic tunnel junction.

One or both of the magnetization layers 140p or 140f can be made of an alloy that contains one or more metals, including, for example, Co, Fe and Ni. For example, a magnetic layer made of a CoFeB compound can be used as the magnetization layers 140p or 140f. In particular, the fixed magnetization layer 140p can have a structure in which magnetic layers and antiferromagnetic layers of, for example, MnPt or MnIr are stacked over one another. The antiferromagnetic layer allows the free magnetization layer 140f to be subjected to magnetization reversal, but does not allow the fixed magnetization layer 140p to be subjected to magnetization reversal. Also, the fixed magnetization layer 140p can have a Synthetic Antiferromagnetic (SAF) structure in which a nonmagnetic layer, such as a Ru layer, is interposed between two magnetic layers.

In addition, the tunnel barrier layer can be made of a metal or non-metal compound containing oxygen. For example, the material of the insulating layer 140b can include one or more selected from the group consisting of AlO, TiO, MgO, HfO, CuO, NiO, and CoO.

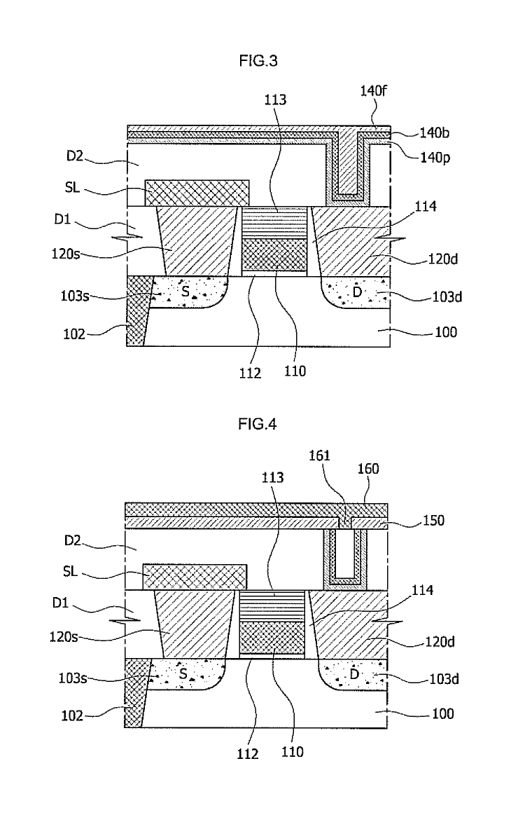

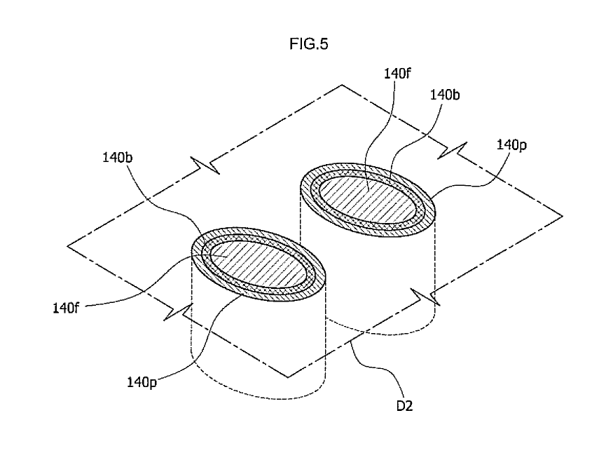

Next, as shown in FIG. 4, portions of the magnetization layer 140p, the insulating layer 140b, and the magnetization layer 140f that are located above the second interlayer layer D2 are removed by planarization (e.g. chemical-mechanical polishing), until the upper surface of the second interlayer dielectric layer D2 is exposed. As a result, remaining portions of the magnetization layer 140p, the insulating layer 140b, and the free magnetization layer 140f, which remain in the form of a cylinder in the opening 130, form a magnetic tunnel junction element. Afterwards, a hard mask layer 150 is formed over the second interlayer dielectric layer D2, a bit line 160 is formed over the hard mask layer 150, and a bit line contact 161 is formed so as to form an electrical connection between the bit line 160 and the free magnetization layer 140f. Finally, a magnetic memory element, including the magnetic tunnel junction element, is produced by typical semiconductor processing.

According to this embodiment of the invention, in the case of forming a magnetic tunnel junction element having a heterogeneous structure in which multiple layers of different materials, such as a magnetization layer and an insulating layer, are stacked over one another, patterning is not used, unlike the related art. This consequently makes it possible to avoid difficulties that would otherwise arise during the process of etching the heterogeneous structure. In particular, oxidation in the process of etching may degrade the characteristics of the element, if a material containing a transition metal is used for the material of the magnetization layer. However, in this embodiment of the invention, the magnetic tunnel junction element is formed by filling the magnetic tunnel junction in the opening of the interlayer dielectric layer using planarization instead of etching. As a result, the problem of oxidation of the transition metal does not occur.

In addition, in this embodiment of the invention, it is possible to produce a cylinder-shaped magnetic tunnel junction element by forming an opening in an interlayer dielectric layer and stacking magnetization and insulating layers in the opening. FIG. 5 illustrates, in a Three-Dimensional (3D) view, two cylindrical magnetic tunnel junction elements, which are produced by forming two openings 130 in an interlayer dielectric layer D2 and forming magnetization layers and an insulating layer to fill the openings 130.

As shown in FIG. 5, the magnetic tunnel junction elements can be formed to have a minimal area. Regardless of the minimization of the area in which the magnetic tunnel junction elements are to be formed, the contact area between the magnetization layer and the tunnel barrier layer can be effectively increased due to the cylindrical structure. This, as a result, can overcome the problem of superparamagnetism, which would otherwise occur in a magnetic tunnel junction due to the high-density integration of the memory device. Accordingly, it is possible to fabricate high density magnetic memory devices while ensuring the stable and reliable operation of the devices.

The foregoing descriptions of specific exemplary embodiments of the present invention have been presented for purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application to thereby enable others skilled in the art to make and utilize various exemplary embodiments of the present invention, as well as various alternatives and modifications thereof. It is intended that the scope of the invention be defined by the claims appended hereto and their equivalents.

What is claimed is:

1. A method for fabricating a semiconductor memory device, comprising:
forming an interlayer dielectric layer over a semiconductor substrate including a metal-oxide-semiconductor field-effect transistor as a cell transistor and a plurality of contact plugs in contact with source and drain regions of the cell transistor;
forming a plurality of openings exposing one of the contact plugs by removing a portion of the interlayer dielectric layer;
sequentially stacking a fixed magnetization layer, a tunnel barrier layer, and a free magnetization layer over the interlayer dielectric layer including the openings; and
forming a magnetic tunnel junction element by planarizing the is interlayer dielectric layer until a surface of the interlayer dielectric layer is exposed, wherein the magnetic tunnel junction element includes the fixed magnetization layer, the tunnel barrier layer, and the free magnetization layer that fill each of the openings.

2. The method in accordance with claim 1, wherein, in the sequentially stacking of the fixed magnetization layer, the tunnel barrier layer, and the free magnetization layer, the fixed magnetization layer is formed to cover sidewalls and bottoms of the openings, the tunnel barrier layer is stacked over the fixed magnetization layer to form a recess in a central portion of the openings, and the free magnetization layer is stacked over the tunnel barrier layer to fill the recess.

3. The method in accordance with claim 1, wherein the fixed magnetization layer or the free magnetization layer comprises an alloy containing one or more metals selected from the group consisting of Co, Fe, and Ni.

4. The method in accordance with claim 1, wherein the fixed magnetization layer has a stacked structure, in which ferromagnetic and antiferromagnetic layers are stacked over one another, or a synthetic antiferromagnetic structure.

5. The method in accordance with claim 1, wherein the tunnel barrier layer comprises a metal or non-metal compound containing oxygen.

6. The method in accordance with claim 5, wherein the tunnel barrier layer contains one or more compounds selected from the group consisting of AlO, TiO, MgO, HfO, CuO, NiO, and CoO.

7. A semiconductor memory device comprising:
a unit memory cell including a metal-oxide-semiconductor field-effect transistor as a cell transistor and a magnetic tunnel junction element,
wherein the magnetic tunnel junction element fills an opening in an interlayer dielectric layer, and comprises:
a fixed magnetization layer covering walls of the opening;
a tunnel barrier layer stacked over the fixed magnetization layer to form a recess in a central portion of the opening; and
a free magnetization layer stacked over the tunnel barrier layer to fill the recess.

8. The semiconductor memory device in accordance with claim 7, wherein the fixed magnetization layer is connected to a drain of the cell transistor.

9. The semiconductor memory device in accordance with claim 7, wherein the fixed magnetization layer or the free magnetization layer comprises an alloy containing one or more metals selected from the group consisting of Co, Fe, and Ni.

10. The semiconductor memory device in accordance with claim 7, wherein the fixed magnetization layer has a stacked structure, in which ferromagnetic and antiferromagnetic layers are stacked over one another, or a synthetic antiferromagnetic structure.

11. The semiconductor memory device in accordance with claim 7, wherein the tunnel barrier layer comprises a metal or non-metal compound containing oxygen.

12. The semiconductor memory device in accordance with claim 11, wherein the tunnel barrier layer contains one or more compounds selected from the group consisting of AlO, TiO, MgO, HfO, CuO, NiO, and CoO.
